(19) United States
(12) Patent Application Publication
(10) Pub. No.: US 2011/0121308 A1
(43) Pub. Date: May 26, 2011

(54) THIN FILM TRANSISTOR AND MANUFACTURING METHOD THEREOF

(75) Inventors: Jae-Sang Ro, Seoul (KR); Won-Eui Hong, Seoul (KR)

(73) Assignee: ENSILTECH CORPORATION, Seoul (KR)

(21) Appl. No.: 13/055,041

(22) PCT Filed: Jul. 8, 2009
(86) PCT No.: PCT/KR09/03744

§ 371 Date: Jan. 20, 2011

(30) Foreign Application Priority Data
Jul. 25, 2008 (KR) 10-2008-0072990

(51) Int. Cl. H01L 29/786; H01L 21/336

(52) U.S. Cl. 257/66; 438/164; 257/E29.293; 257/E21.413

(57) ABSTRACT

Provided are a thin film transistor including a polycrystalline silicon layer having improved crystallinity by applying Joule heat to form stress gradient in a glass substrate that is disposed under an amorphous silicon layer from a surface to a predetermined depth of the glass substrate, thereby crystallizing the amorphous silicon layer into a polycrystalline silicon layer, and a method of fabricating the same. The film transistor includes a glass substrate having stress gradient from an upper surface to a predetermined depth, a semiconductor layer disposed on the glass substrate, and formed of a polycrystalline silicon layer crystallized by Joule heating, a gate insulating layer disposed on the semiconductor layer, a gate electrode disposed on the gate insulating layer, an interlayer insulating layer disposed on the gate electrode, and source and drain electrodes disposed on the interlayer insulating layer, and electrically connected to source and drain regions of the semiconductor layer.

### TECHNICAL FIELD

The present invention relates to a thin film transistor and a method of fabricating the same, and more particularly, to a thin film transistor including a polycrystalline silicon layer having improved crystallinity by applying Joule heat to have stress gradient in a glass substrate, which underlies an amorphous silicon layer, from a surface of the glass substrate to a predetermined depth thereof, and crystallizing the amorphous silicon layer into a polycrystalline silicon layer, and a method of fabricating the same.

### BACKGROUND ART

Among various techniques of fabricating flat panel display devices, research into an active-matrix flat panel display device using a thin film transistor has been actively conducted in recent times. Conventionally, a semiconductor layer of a thin film transistor has been formed of amorphous silicon. However, amorphous silicon generally has low mobility of electrons as charge carriers and a low aperture ratio, and is not suitable for a CMOS process.

On the other hand, in a polycrystalline silicon thin film transistor (TFT), a driving circuit necessary to write an image signal on a pixel, which was impossible with an amorphous silicon TFT, can be installed on a substrate as in a pixel TFT-array. Thus, in the polycrystalline silicon TFT, a plurality of terminals are not necessarily in contact with a driver IC, so that productivity and reliability can be increased, and a thickness of a panel can be reduced. Since, in the polycrystalline silicon TFT process, micro-processing of silicon LSI can be used as is, a micro-interconnection may be formed. Accordingly, since there are no pitch limits in bonding the driver IC in a TAB process, as there are in the amorphous silicon TFT, pixel reduction is easy and a plurality of pixels may be realized within a small pixel angle. Compared to the TFT using amorphous silicon, the TFT using polycrystalline silicon for a semiconductor layer has high switching ability, and determines a channel position on the semiconductor layer by self-alignment, so that the scaling-down of the device and the application of CMOS technology are possible. For these reasons, the polycrystalline TFT has come into the limelight as an essential device for large-sized displays when used as a pixel switching device for an active matrix flat panel display device (e.g., a liquid crystal display device, or an organic light emitting diode display device) and practical use of a chip-on-glass (COG) in which a driver is installed.

Methods of fabricating this polycrystalline silicon TFT include high temperature methods and low temperature methods. For the high temperature methods, a high-cost material such as quartz must be used as a substrate, which is not suitable for a large area process. Thus, research into converting an amorphous silicon thin film into a polycrystalline silicon thin film at low temperature on a large scale has been actively conducted.

Examples of methods of forming polycrystalline silicon at low temperature include solid phase crystallization (SPC), metal induced crystallization (MIC), metal induced lateral crystallization (MILC) and excimer laser crystallization (ELC) methods.

The SPC method may ensure uniform crystal quality using low-cost equipment, but since it requires a high crystallization temperature and a long processing time, a substrate having a relatively low heat deflection temperature such a glass substrate may not be used, and productivity is low. According to the SPC method, crystallization can be generally performed by annealing the amorphous silicon thin film for about 1 to 24 hours at 600 to 700° C. In addition, the polycrystalline silicon formed by the SPC method undergoes twin-growth in solid phase transformation from an amorphous phase to a crystal phase, so that many crystal lattice defects are contained in formed crystal grains. These factors decrease mobility of electrons and holes of the fabricated polycrystalline silicon TFT, and increase a threshold voltage.

According to the MIC method, crystallization is performed at a lower temperature than the crystallization temperature for the SPC method since amorphous silicon is in contact with a specific metal. Metals for the MIC method include nickel (Ni), palladium (Pd), titanium (Ti), aluminum (Al), silver (Ag), gold (Au), cobalt (Co), copper (Cu), iron (Fe) and manganese (Mn), each of which reacts with the amorphous silicon, thereby forming a eutectic phase or a silicide phase and stimulating low temperature crystallization. However, in a practical process of fabricating a polycrystalline silicon TFT, the MIC method brings about serious contamination of a metal in a channel.

The MILC method is an application of the MIC method, which includes forming a gate electrode instead of depositing a metal on a channel, depositing a thin metal on a source and a drain in a self-aligned structure to perform metal-induced crystallization, and inducing lateral crystallization toward the channel. Metals usually used for the MILC method include Ni and Pd. Polycrystalline silicon formed by the MILC method has better crystallinity and higher field effect mobility than that formed by the SPC method, but has a high leakage current. That is, while this method reduces the metal contamination occurring in the MIC method, it does not completely overcome this problem. Meanwhile, a field-aided lateral crystallization (FALC) method has been introduced as an improvement on the MILC method. The FALC method has a fast crystallization rate and anisotropy in a crystallization direction, but this method does not completely overcome the metal contamination, either.

The above-described crystallization methods, including the MIC, MILC, and FALC methods, are effective in lowering the crystallization temperature as compared with the SPC method. However, all of these methods still require a long crystallization time, and are metal-induced crystallization methods. Thus, these methods are not free from metal contamination. The recently developed ELC method solves the problem of metal contamination, and enables fabrication of a polycrystalline silicon thin film on a glass substrate through a low temperature process. Amorphous silicon thin films deposited by low pressure chemical vapor deposition (LPCVD) or plasma enhanced chemical vapor deposition (PECVD) have very high absorption coefficients with respect to an ultra-violet range (λ=308 nm), which is an excimer laser wavelength, so that the amorphous silicon thin film easily melts at a proper energy density. When the amorphous silicon thin film is crystallized using an excimer laser, both melting and solidification occur in a very short period of time. At this point, strictly speaking, the ELC method is not a low temperature process. However, in the ELC process, crystallization includes melting and solidification, which are very rapidly performed in a local melting area greatly influenced by the excimer laser. Thus, polycrystalline silicon may be formed in a very short period of time (in a unit of tens of ns) without damage to a substrate. That is, when a laser is applied to amorphous silicon of a base material including a glass substrate, an insulating layer and an amorphous silicon thin film for a very short period of time, only the amorphous silicon thin film is selectively annealed, and thus crystallization is performed without damage to the underlying glass substrate. In addition, polycrystalline silicon produced in phase transformation from a liquid phase to a solid phase has a more thermodynamically stable crystal grain structure, and significantly fewer defects in the crystal grains than polycrystalline silicon produced through solid phase crystallization. As a result, the polycrystalline silicon formed by the ELC method has better characteristics than the results formed by the other crystallization methods.

Nevertheless, the ELC method has some critical disadvantages, which include: a problem of a laser system having a non-uniform dose of applied laser beams, a problem of a laser process having an ultimately limited process area of a laser energy density causing a coarse crystal grain, and a problem of a shot stain in a large area. The limited process area and the shot stain result in non-uniformity in crystal grain size of a polycrystalline silicon thin film constituting an active layer of the polycrystalline TFT. In addition, the polycrystalline silicon generated with the phase transformation from a liquid phase to a solid phase is increased in volume, so that severe protrusion occurs toward a surface from a location in which a crystal grain boundary is formed. This protrusion directly affects a gate insulating layer to be formed in a subsequent process, and seriously affects the device's reliability including reduction of a breakdown voltage due to non-uniform flatness at an interface between the polycrystalline silicon and the gate insulating layer, and a hot carrier stress.

To solve the instability of the ELC method described above, a recently developed sequential lateral solidification (SLS) method achieves stabilization of the process area of the laser energy density, but it has yet to overcome the shot stain and the protrusion toward the surface. In addition, considering a current trend of a rapidly developing flat panel display industry, use of a laser for a process of crystallizing a substrate having a size of 1 m×1 m or larger, which will be necessary for mass-production, still has problems. Moreover, equipment for the ELC and SLS methods are very expensive, so that high costs of initial investment and maintenance are required.

Accordingly, there is a need for a method of crystallizing an amorphous silicon thin film, which has the advantages of the laser crystallization method, i.e., a short processing time, no damage to the underlying substrate, and production of high quality crystal grain having almost no defects due to high temperature phase transformation, and overcomes the disadvantages of the laser crystallization method, i.e., non-uniformity in dose of an applied laser beam and process limits according to a local process, and use of high-cost equipment. Particularly, an active-matrix organic light emitting diode recently receiving great attention in application to a next generation flat panel display is operated in a current driving method, whereas a TFT-LCD is operated in a voltage driving method. Thus, uniformity in crystal grain size in a large-sized substrate becomes a very critical factor. For this reason, the low temperature crystallization through the ELC or SLS method using a laser has limits, which is the current problem that the flat panel display industry faces. Considering this, new techniques for fabricating a high-quality polycrystalline silicon thin film by low temperature crystallization without using a laser are highly sought after.

To solve these conventional problems, a method of crystallizing a silicon thin film by pre-heating a silicon thin film within a temperature range without deformation of a substrate during the process to generate an intrinsic carrier in the silicon thin film, lowering a resistance value to be suitable for Joule heating, and directly applying an electric field to the pre-heated silicon thin film to perform Joule heating due to migration of the carrier has been disclosed for the first time by the present inventors in Korean Patent Application No. 2004-37952. This method is a very innovative method for fabricating a high-quality polycrystalline silicon thin film in a very short period of time at relatively low temperature.

A better method of crystallizing a silicon thin film by forming an ITO layer as a conductive layer, and an insulating layer on an insulating layer formed on a transparent substrate, forming a silicon thin film thereon, and applying an electric field to the ITO layer to induce Joule heating to generate high heat, thereby preventing damage to the substrate due to the high heat at a lower temperature than the conventional art, and particularly, at room temperature, for a very short period of time, and a dopant activation and thermal oxide layer process and a method of curing crystal lattice defects have also been disclosed by the present inventors in Korean Patent Application No. 2005-73076.

However, to be used as a semiconductor layer of a thin film transistor of a flat panel display device, which is getting larger, a thin film crystallized using Joule heating needs to have more improved crystallinity than the conventional polycrystalline silicon layer.

### DISCLOSURE

### Technical Problem

The present invention is directed to a thin film transistor including a polycrystalline silicon layer having good crystallinity and a method of fabricating the same.

### Technical Solution

One aspect of the present invention provides a thin film transistor, including: a glass substrate having stress gradient from an upper surface to a predetermined depth; a semiconductor layer disposed on the glass substrate, and formed of a polycrystalline silicon layer crystallized by Joule heating; a gate insulating layer disposed on the semiconductor layer; a gate electrode disposed on the gate insulating layer; an interlayer insulating layer disposed on the gate electrode; and source and drain electrodes disposed on the interlayer insulating layer, and electrically connected to source and drain regions of the semiconductor layer.

Another aspect of the present invention provides a method of fabricating a thin film transistor, including: preparing a glass substrate; forming an amorphous silicon layer on the glass substrate; sequentially forming an insulating layer and a conductive layer on the amorphous silicon layer; crystallizing the amorphous silicon layer into a polycrystalline silicon layer by applying an electric field having an energy of power density that can generate high heat of 1300° C. or more to the conductive layer for 0.1 to 300 μs; removing the insulating layer and the conductive layer; forming a semiconductor layer by patterning the polycrystalline silicon layer; forming a gate insulating layer on the semiconductor layer; forming a gate electrode on the gate insulating layer; forming an interlayer insulating layer on the gate electrode; and forming source and drain electrodes electrically connected to source and drain regions of the semiconductor layer on the interlayer insulating layer.

Still another aspect of the present invention provides a method of fabricating a thin film transistor, including: preparing a glass substrate; sequentially forming a conductive layer and an insulating layer on the glass substrate; forming an amorphous silicon layer on the insulating layer; crystallizing the amorphous silicon layer into a polycrystalline silicon layer by applying an electric field having an energy of power density that can generate high heat of 1300° C. or more to the conductive layer for 0.1 to 300 μs; forming a semiconductor layer by patterning the polycrystalline silicon layer; forming a gate insulating layer on the semiconductor layer; forming a gate electrode on the gate insulating layer; forming an interlayer insulating layer on the gate electrode; and forming source and drain electrodes electrically connected to source and drain regions of the semiconductor layer on the interlayer insulating layer.

Yet another aspect of the present invention provides a method of fabricating a thin film transistor, including: preparing a glass substrate; forming an amorphous silicon layer pattern on the glass substrate; forming a gate insulating layer on the amorphous silicon layer pattern; forming a first contact hole exposing a predetermined region of the amorphous silicon layer pattern by etching a predetermined region of the gate insulating layer; forming a gate electrode material on the gate insulating layer; forming a semiconductor layer by crystallizing the amorphous silicon layer pattern into a polycrystalline silicon layer by applying an electric field having an energy of power density that can generate high heat of 1300° C. or more to the gate electrode material for 0.1 to 300 μs; forming a gate electrode by patterning the gate electrode material; forming an interlayer insulating layer on the entire surface of the glass substrate having the gate electrode; forming a second contact hole exposing the predetermined region of the semiconductor layer exposed through the first contact hole by etching a predetermined region of the interlayer insulating layer; and forming source and drain electrodes electrically connected to source and drain regions of the semiconductor layer through the first contact hole and the second contact hole on the interlayer insulating layer.

### Advantageous Effects

According to the present invention, a thin film transistor including a polycrystalline silicon layer having good crystallinity and a method of fabricating the same can be provided.

### DESCRIPTION OF DRAWINGS

FIGS. 1 to 3 are cross-sectional views showing a process of fabricating a thin film transistor according to a first exemplary embodiment of the present invention;

FIGS. 4 to 6 are cross-sectional views showing a process of fabricating a thin film transistor according to a second exemplary embodiment of the present invention;

FIGS. 7 to 10 are cross-sectional views showing a process of fabricating a thin film transistor according to a third exemplary embodiment of the present invention;

FIGS. 11 and 12 are transmission electron microscope (TEM) photographs of polycrystalline silicon layers crystallized according to Example and Comparative Example, respectively; and

FIG. 13 is a scanning electron microscope (SEM) photograph of a section of a device used in Example.

### *DESCRIPTION OF MAJOR SYMBOL IN THE ABOVE FIGURES

101, 201 and 301: glass substrate
102, 202 and 302: buffer layer
103 and 205: conductive layer
104 and 204: insulating layer
105, 203 and 303: amorphous silicon layer
106, 206 and 307: semiconductor layer
107, 207 and 304: gate insulating layer
108, 208 and 308: gate electrode
306: gate electrode material
109, 209 and 309: interlayer insulating layer
111, 112, 211, 212, 311 and 312: source and drain electrodes

### MODE FOR INVENTION

Hereinafter, exemplary embodiments of the present invention will be described in detail. However, the present invention is not limited to the exemplary embodiments disclosed below, but can be implemented in various types.

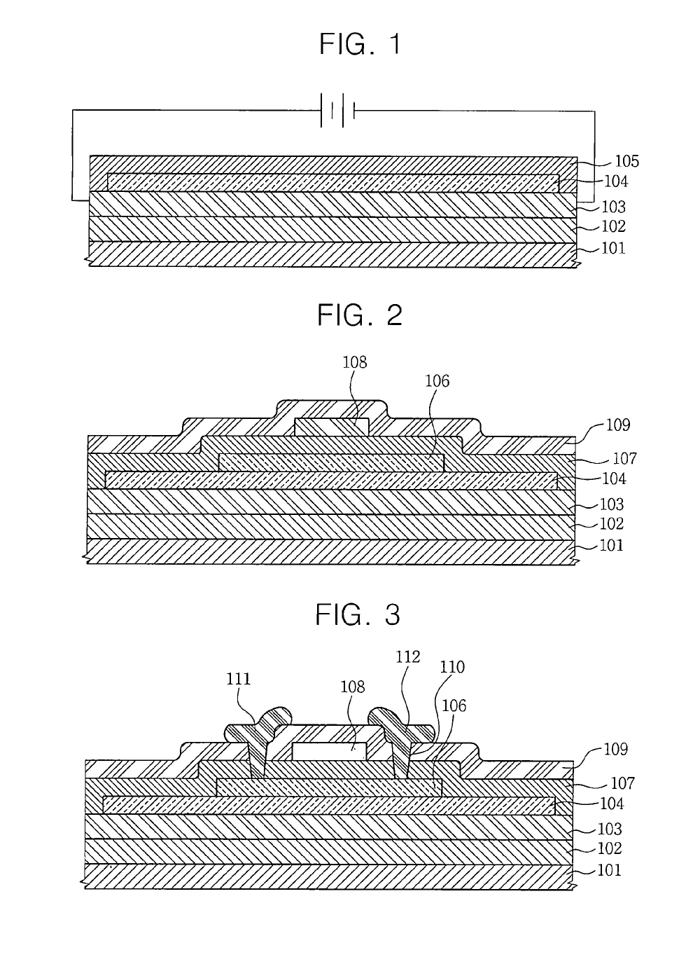

FIGS. 1 to 3 are cross-sectional views showing a process of fabricating a thin film transistor according to a first exemplary embodiment of the present invention.

Referring to FIG. 1, a buffer layer 102 is formed on a glass substrate 101. The glass substrate 101 may be formed to a thickness of 600 to 800 μm, but the present invention is not limited thereto.

The buffer layer 102 is used to prevent out-diffusion of some materials in the glass substrate 101 which will be formed in a subsequent process, for example, alkali materials, and is generally formed by depositing silicon oxide or silicon nitride. The buffer layer 102 may usually be formed to a thickness of 2000 to 5000 Å, but the present invention is not limited thereto. The buffer layer 102 may be omitted, and a method of the present invention may be applied to such a structure. Therefore, the scope of the present invention should be construed to include this structure.

Subsequently, a conductive layer 103 is formed on the buffer layer 102. The conductive layer 103 may be formed of a transparent conductive thin film or metal thin film. The conductive layer 103 may be formed of a metal thin film having a melting point of 1300° C. or more. To crystallize an amorphous silicon layer 105 which will be subsequently formed for a very short period of time, e.g., 0.1 to 300 μs, high heat having a temperature of 1300° C. or more may be instantaneously applied to the amorphous silicon layer 105. To prevent damage to the conductive layer 103 from the high heat, the conductive layer 103 may be formed of a metal thin film having a melting point of 1300° C. or more. Examples of metals having a melting point of 1300° C. or more include molybdenum (Mo), titanium (Ti), chromium (Cr) and molybdenum-tungsten (MoW). The conductive layer 103 may be formed by sputtering or evaporation, and have a thickness of 500 to 3000 Å, but the present invention is not limited thereto.

An insulating layer 104 is formed on the conductive layer 103. The insulating layer 104 may act to prevent contamination of the amorphous silicon layer 105 due to the conductive layer 103 during annealing, and insulate a TFT device. The insulating layer 104 may be formed of the same material as the buffer layer 102.

Subsequently, the amorphous silicon layer 105 is formed on the insulating layer 104. The amorphous silicon layer 105 may be formed by low pressure chemical vapor deposition (LPCVD), atmospheric pressure chemical vapor deposition (APCVD), plasma enhanced chemical vapor deposition (PECVD), sputtering or vacuum evaporation, and preferably PECVD. The amorphous silicon layer 105 may be formed to a thickness of 500 to 2000 Å.

Then, an electric field is applied to the conductive layer 103 to form the amorphous silicon layer 105 into a polycrystalline silicon layer by Joule heating. The electric field is applied to the conductive layer 103 to have stress gradient in the glass substrate 101 from an upper surface to a predetermined depth thereof. To this end, an energy of power density that can apply high heat of 1300° C. or more to the amorphous silicon layer 105 is applied for a very short period of time, e.g., 0.1 to 300 μs. Here, an energy of 100000 W/cm² or more may be applied to the conductive layer 103.

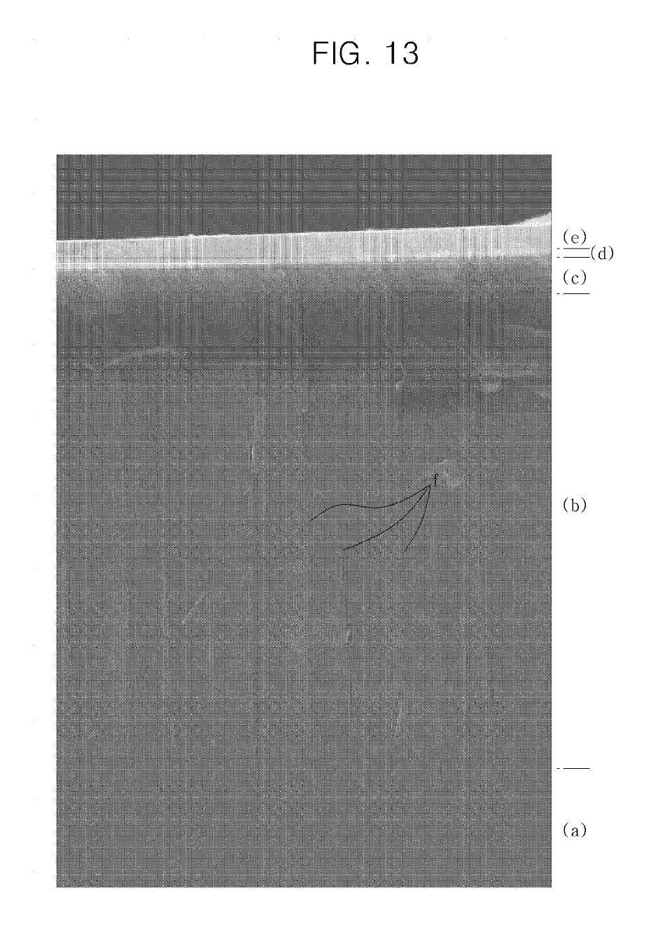

When the electric filed having an energy of power density capable of applying high heat of 1300° C. or more to the amorphous silicon layer 105 is applied to the conductive layer 103 for a very short period of time, e.g., 0.1 to 300 μs, a certain amount of heat is transferred to the glass substrate 101. Here, looking inside the glass substrate 101, devices disposed on the glass substrate 101 are heated and expand, and thus compressive stress is applied to the devices. On the other hand, below an area ranging from the surface of the glass substrate 101 to the predetermined depth to which heat is not transferred, tensile stress is applied. After annealing, the tensile stress is formed between the devices and the compressive stress is formed toward the glass substrate 101. As a result, stress gradient is formed from the upper surface of the glass substrate 101 to the predetermined depth thereof. As such, the polycrystalline silicon layer crystallized on the glass substrate 101 having the stress gradient therein has a crystal grain having almost no crystal defects, and good crystallinity. After the glass substrate 101 having this stress gradient therein is cut, it can be confirmed from a section that a fine crack is formed from the surface of the glass substrate 101 to the predetermined depth thereof, as shown in FIG. 13. In addition, the section has a wave-patterned curve.

In the crystallization method by Joule heating, the electric field is applied only to the conductive layer 103 to induce Joule heating. Thus, the glass substrate 101 is heated, not entirely, but only from the surface of the glass substrate 101 to a predetermined depth thereof, and below the predetermined depth, the glass substrate 101 is still at room temperature. Therefore, in the glass substrate 101, stress gradient may be formed from the surface to the predetermined depth. However, in a solid phase crystallization method in which the entire glass substrate having a device is input to a furnace to be heated, the entire glass substrate is heated and expands, such that stress gradient cannot be formed from the surface to the predetermined depth of the glass substrate like the present invention.

A depth range in which the stress gradient is formed may be from the surface of the glass substrate 101 to 10 μm. It is preferable in an aspect of mechanical strength of the glass substrate 101 that the stress gradient be formed from the surface of the glass substrate 101 to 10 μm.

A time to apply the electric field to the conductive layer 103 may be 0.1 to 300 μs. When the electric field is applied for less than 0.1 μs, the amorphous silicon layer 105 may not be crystallized into a polycrystalline silicon layer, and when the electric field is applied for more than 300 μs, stress gradient may be formed from the surface of the glass substrate to a depth of 10 μm or more. Thus, it is preferable in an aspect of the mechanical strength of the glass substrate 101 that the electric field may be applied to the conductive layer 103 for 300 μs or less.

The polycrystalline silicon layer has conductivity at high temperature. Thus, when the amorphous silicon layer 105 is crystallized into the polycrystalline silicon layer by applying the electric field to the conductive layer 103 upon interposing the insulating layer 104 between the conductive layer 103 and the amorphous silicon layer 105 to induce Joule heating, a capacitor structure is formed. When a potential difference generated at this time exceeds a breakdown voltage of the insulating layer 104, a current flows through the insulating layer 104, thereby generating an arc. To prevent this phenomenon, a part of the insulating layer 104 may be etched before forming the amorphous silicon layer 105, to expose a predetermined region of the conductive layer 103, and the amorphous silicon layer 105 is then formed on the exposed conductive layer 103 and the insulating layer 104 to be in contact with the predetermined region of the conductive layer 103 during crystallization.

Subsequently, referring to FIG. 2, a semiconductor layer 106 is formed by patterning the polycrystalline silicon layer.

Then, a gate insulating layer 107 is formed on the semiconductor layer 106. The gate insulating layer 107 may be a silicon oxide layer, a silicon nitride layer or a combination thereof.

A metal layer for a gate electrode (not shown) is formed on the gate insulating layer 107 in a single layer structure of aluminum (Al) or an aluminum alloy such as aluminum-neodymium (Al—Nd), or in a multilayer structure in which an aluminum alloy is stacked on a chromium (Cr) or molybdenum (Mo) alloy, and etched by photolithography and etching processes to form a gate electrode 108 in a part corresponding to a channel region of the semiconductor layer 106.

Subsequently, an interlayer insulating layer 109 is formed on the entire substrate having the gate electrode 108. Here, the interlayer insulating layer 109 may be a silicon nitride layer, a silicon oxide layer or a combination thereof.

Referring to FIG. 3, the interlayer insulating layer 109 and the gate insulating layer 107 are etched to form a contact hole 110 exposing a predetermined region in a source or drain region of the semiconductor layer 106.

Then, source and drain electrodes 111 and 112 connected to the source and drain regions of the semiconductor layer 106 through the contact holes 110 are formed on the interlayer insulating layer 109.

FIGS. 4 to 6 are cross-sectional views showing a process of fabricating a thin film transistor according to a second exemplary embodiment of the present invention. A process will be described with reference to the above-mentioned exemplary embodiments except as specifically described below.

Referring to FIG. 4, a buffer layer 202 is formed on a glass substrate 201. After that, an amorphous silicon layer 203, an insulating layer 204 and a conductive layer 205 are sequentially formed on the buffer layer 202.

Subsequently, an electric field having an energy of power density capable of applying high heat of 1300° C. or more to the amorphous silicon layer 203 is applied to the conductive layer 205 for a very short period of time, e.g., 0.1 to 300 μs, such that stress gradient is formed in the glass substrate 201 from a surface of the glass substrate 201 to a predetermined depth thereof, thereby crystallizing the amorphous silicon layer 203 into a polycrystalline silicon layer. To this end, an energy of 100000 W/cm² or more may be applied to the conductive layer 205. A depth range in which the stress gradient is formed may be from the surface of the glass substrate 201 to 10 μm.

Subsequently, referring to FIG. 5, the insulating layer 204 and the conductive layer 205 are removed, and the polycrystalline silicon layer is patterned, thereby forming a semiconductor layer 206. A gate insulating layer 207 is then formed on the semiconductor layer 206, and a gate electrode 208 is formed in a part corresponding to a channel region of the semiconductor layer 206. An interlayer insulating layer 209 is then formed on the entire substrate having the gate electrode 208.

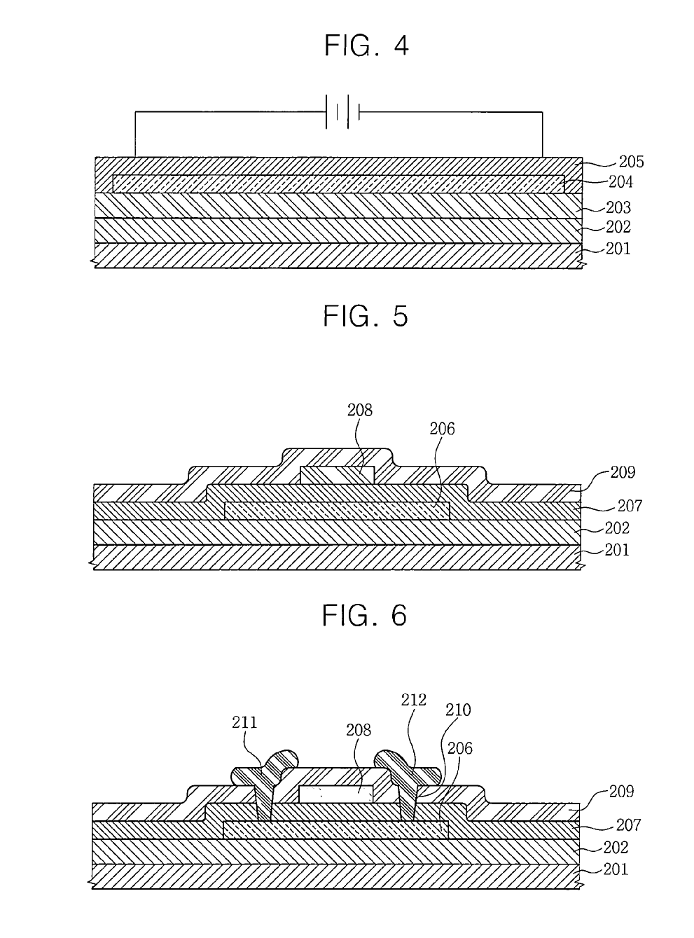

Referring to FIG. 6, the interlayer insulating layer 209 and the gate insulating layer 207 are etched to form a contact hole 210 exposing a predetermined region in a source or drain region of the semiconductor layer 206. Source and drain electrodes 211 and 212 connected to the source and drain regions of the semiconductor layer 206 through the contact hole 210 are then formed.

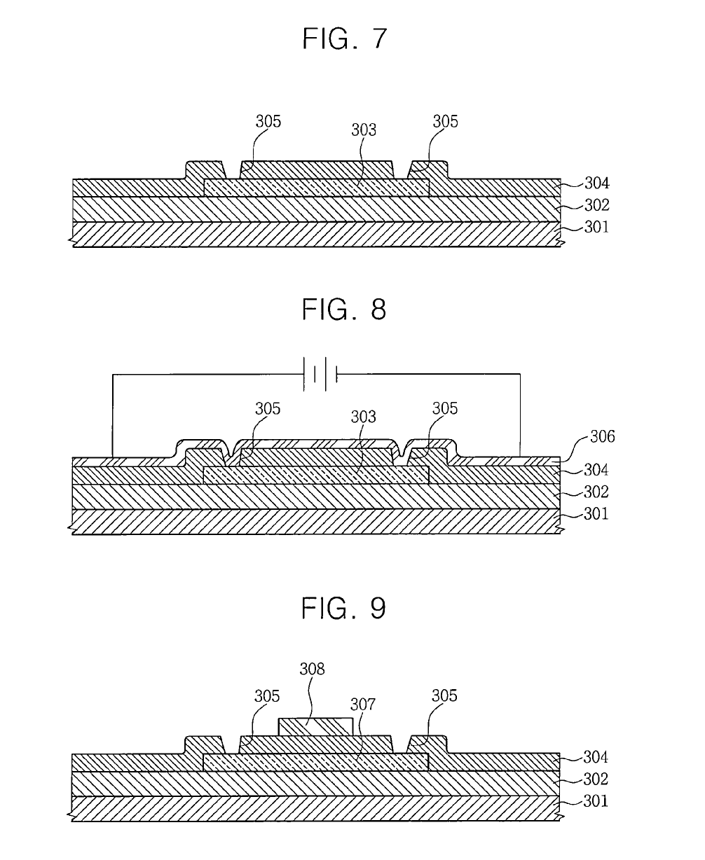

FIGS. 7 to 10 are cross-sectional views showing a process of fabricating a thin film transistor according to a third exemplary embodiment of the present invention. A process will be described with reference to the above-mentioned exemplary embodiments except as specifically described below.

Referring to FIG. 7, a buffer layer 302 is formed on a glass substrate 301. An amorphous silicon layer is then formed on the buffer layer 302 and patterned, thereby forming an amorphous silicon layer pattern 303. Subsequently, a gate insulating layer 304 is formed on the amorphous silicon layer pattern 303. A predetermined region of the gate insulating layer 304 is etched to expose a predetermined region of the amorphous silicon layer pattern 303 to be formed into source and drain regions of a semiconductor layer, thereby forming a first contact hole 305 in the gate insulating layer 304.

Referring to FIG. 8, a gate electrode material 306 is formed on the entire surface of the glass substrate 301 having the gate insulating layer 304. When an electric field having an energy of power density capable of applying high heat of 1300° C. or more to the amorphous silicon layer pattern 303 is applied to the gate electrode material 306 for a very short period of time, e.g., 0.1 to 300 μs, such that stress gradient is formed in the glass substrate 301 from a surface of the glass substrate 301 to a predetermined depth thereof, and thus the amorphous silicon layer pattern 303 is crystallized into a polycrystalline silicon layer pattern. The crystallized polycrystalline silicon layer pattern becomes a semiconductor layer 307 (in FIG. 9). To this end, an energy of 100000 W/cm² or more may be applied to the gate electrode material 306. A depth range in which the stress gradient is formed may be from the surface of the glass substrate 301 to 10 μm.

Referring to FIG. 9, the gate electrode material 306 is patterned to form a gate electrode 308 corresponding to a region that will be defined as a channel region of the semiconductor layer 307.

In the exemplary embodiment, since the gate electrode material 306 used for forming the gate electrode 308 is used as a conductive layer to induce Joule heating, there is no need to form a separate conductive layer. When the gate electrode material 306 is in contact with the amorphous silicon layer pattern 303 during crystallization using the first contact hole 305 for connecting a source or drain electrode to be subsequently formed to the semiconductor layer 307, it may prevent generation of an arc. Here, since a mask for forming a contact hole may be used to etch a predetermined region of the gate insulating layer 304, the predetermined region of the gate insulating layer 304 may be etched without introducing a separate mask, thereby preventing the generation of an arc.

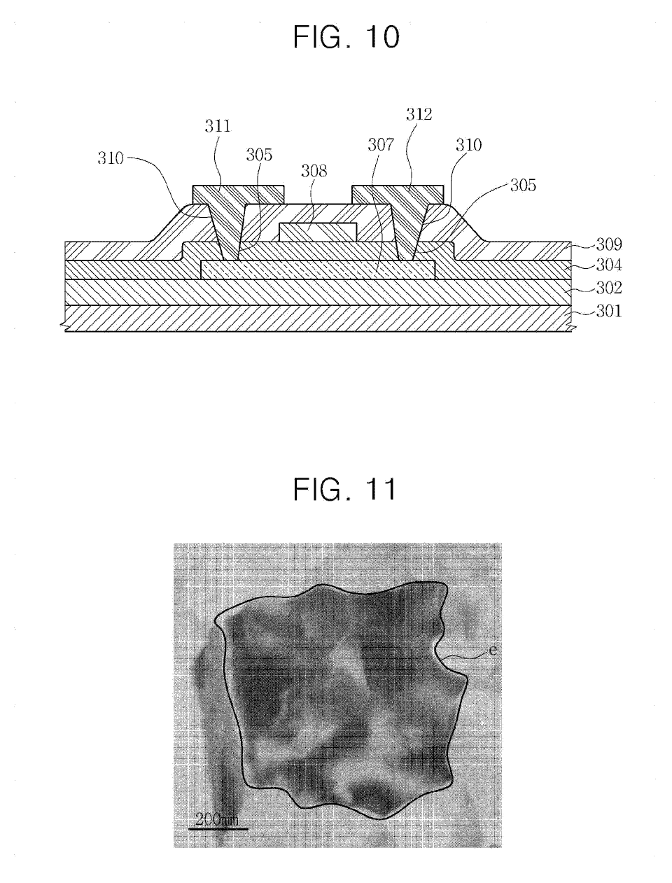

Subsequently, referring to FIG. 10, an interlayer insulating layer 309 is formed on the entire surface of the glass substrate 301. A predetermined region of the interlayer insulating layer 309 is then etched to form a second contact hole 310 exposing a predetermined region of the semiconductor layer 307 exposed through the first contact hole 305. Source and drain electrodes 311 and 312 electrically connected to source and drain regions of the semiconductor layer 307 through the first and second contact holes 305 and 310, respectively, are then formed.

Now, the present invention will be described with reference to Example and Comparative Example, which however do not limit the scope of the present invention.

### Example

A buffer layer was formed by depositing a SiO₂ layer to a thickness of 3000 Å on a glass substrate having a size of 2 cm (length)×2 cm (width)×0.7 mm (height) through PECVD. A conductive layer was formed by depositing a molybdenum layer to a thickness of 1000 Å on the buffer layer through sputtering, and then an insulating layer was formed by depositing a SiO₂ layer to a thickness of 1000 Å through PECVD. An amorphous silicon layer was deposited to a thickness of 500 Å on the insulating layer through PECVD. Subsequently, an energy of 200000 W/cm² was applied to the molybdenum layer of the sample formed as described for 15 μs to induce Joule heating, thereby crystallizing the amorphous silicon layer into a polycrystalline silicon layer. Here, it was estimated that an instantaneous temperature applied to the molybdenum layer increased to 1300° C.

### Comparative Example

An insulating layer was formed by depositing a SiO₂ layer to a thickness of 3000 Å on a glass substrate having a size of 2 cm (length)×2 cm (width)×0.7 mm (height) through PECVD. An amorphous silicon layer was deposited to a thickness of 500 Å on the insulating layer through PECVD. The substrate having the amorphous silicon layer was annealed at 750° C. for 1 hour in a tube furnace, thereby crystallizing the amorphous silicon layer into a polycrystalline silicon layer through solid phase crystallization.

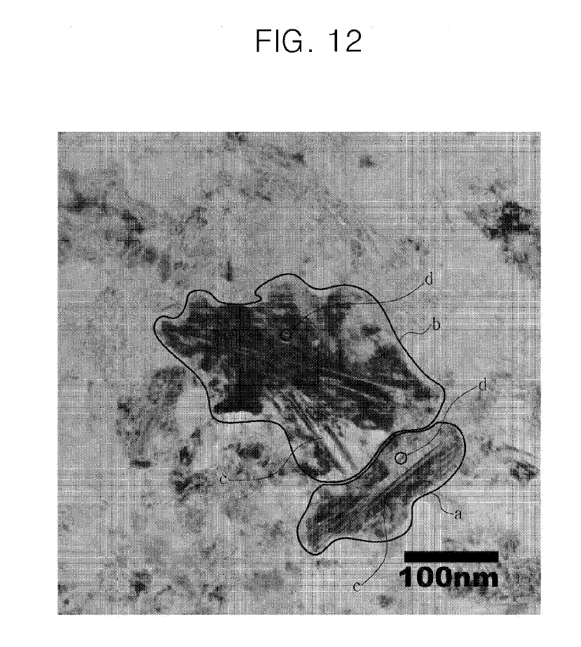

FIGS. 11 and 12 are transmission electron microscope (TEM) photographs of polycrystalline silicon layers crystallized according to Example and Comparative Example, respectively. FIG. 11 is a TEM photograph of a polycrystalline silicon layer crystallized according to Example, and FIG. 12 is a TEM photograph of a polycrystalline silicon layer crystallized according to Comparative Example.

Referring to FIG. 12, in the case of the polycrystalline silicon layer formed according to Comparative Example, though the crystal grains (a and b) are as small as 1000 Å and 2000 Å, respectively, several twins (c) and point defects (d) are observed in both crystal grains (a and b). On the other hand, referring to FIG. 11, in the case of the polycrystalline silicon layer formed according to Example, a grain (e) is three times larger, e.g., 7000 Å, than those in Comparative example, and almost no defects are observed. Thus, it can be confirmed that the polycrystalline silicon layer formed according to Example is significantly increased in crystallinity.

FIG. 13 is a scanning electron microscope (SEM) photograph of a section of a device used in Example.

In FIG. 13, region (a) extends downward from a depth of 10 μm from an upper surface of the glass substrate, region (b) ranges from an upper surface of the glass substrate to a depth of 10 μm, a buffer layer is disposed in region (c), a molybdenum layer is disposed in region (d), and an insulating layer and a polycrystalline silicon layer are disposed in region (e). In region (e), a boundary between the insulating layer formed of SiO₂ and the polycrystalline silicon layer are not clearly shown.

Referring to region (b) of FIG. 13, it can be confirmed that fine cracks (f) are formed from the surface to the depth of 10 μm of the glass substrate after the glass substrate used in Example is cut. According to the result, it can be known that stress gradient is formed in the glass substrate from the upper surface to a predetermined depth thereof.

Thus, the amorphous silicon layer is crystallized into a polycrystalline silicon layer by applying Joule heat to form stress gradient in the glass substrate underlying the amorphous silicon layer from a surface to a predetermined depth thereof, and thus a thin film transistor including a polycrystalline silicon layer having improved crystallinity may be formed.

While the invention has been shown and described with reference to certain exemplary embodiments thereof, it will be understood by those skilled in the art that various changes in form and details may be made therein without departing from the spirit and scope of the invention as defined by the appended claims.

1. A thin film transistor, comprising:
a glass substrate having stress gradient from an upper surface to a predetermined depth;
a semiconductor layer disposed on the glass substrate, and formed of a polycrystalline silicon layer crystallized by Joule heating;
a gate insulating layer disposed on the semiconductor layer;
a gate electrode disposed on the gate insulating layer;
an interlayer insulating layer disposed on the gate electrode; and
source and drain electrodes disposed on the interlayer insulating layer, and electrically connected to source and drain regions of the semiconductor layer.

2. The thin film transistor of claim 1, wherein the stress gradient is formed in the glass substrate from the upper surface to a depth of 10 μm thereof.

3. The thin film transistor of claim 1, wherein when the glass substrate is cut, a section has a wave-patterned curve.

4. The thin film transistor of claim 3, wherein the section has a fine crack formed from the upper surface to a predetermined depth of the glass substrate.

5. The thin film transistor of claim 1, further comprising a buffer layer interposed between the glass substrate and the semiconductor layer.

6. The thin film transistor of claim 5, further comprising:
a conductive layer disposed on the buffer layer; and
an insulating layer disposed on the conductive layer, the both layers being interposed between the buffer layer and the semiconductor layer.

7. The thin film transistor of claim 6, wherein the conductive layer is formed of molybdenum (Mo), titanium (Ti), chromium (Cr) or molybdenum-tungsten (MoW).

8. A method of fabricating a thin film transistor, comprising:
preparing a glass substrate;
forming an amorphous silicon layer on the glass substrate;
sequentially forming an insulating layer and a conductive layer on the amorphous silicon layer;
crystallizing the amorphous silicon layer into a polycrystalline silicon layer by applying an electric field having an energy of power density that can generate high heat of 1300° C. or more to the conductive layer for 0.1 to 300 μs;
removing the insulating layer and the conductive layer;
forming a semiconductor layer by patterning the polycrystalline silicon layer;
forming a gate insulating layer on the semiconductor layer;
forming a gate electrode on the gate insulating layer;
forming an interlayer insulating layer on the gate electrode; and
forming source and drain electrodes electrically connected to source and drain regions of the semiconductor layer on the interlayer insulating layer.

9. A method of fabricating a thin film transistor, comprising:
preparing a glass substrate;
sequentially forming a conductive layer and an insulating layer on the glass substrate;
forming an amorphous silicon layer on the insulating layer;
crystallizing the amorphous silicon layer into a polycrystalline silicon layer by applying an electric field having an energy of power density that can generate high heat of 1300° C. or more to the conductive layer for 0.1 to 300 μs;
forming a semiconductor layer by patterning the polycrystalline silicon layer;
forming a gate insulating layer on the semiconductor layer;
forming a gate electrode on the gate insulating layer;
forming an interlayer insulating layer on the gate electrode; and
forming source and drain electrodes electrically connected to source and drain regions of the semiconductor layer on the interlayer insulating layer.

10. The method of claim 8, wherein, before forming the conductive layer, a predetermined region of the insulating layer is etched to expose a predetermined region of the amorphous silicon layer, and the conductive layer is formed on the exposed amorphous silicon layer and the insulating layer.

11. The method of claim 9, wherein, before forming the amorphous silicon layer, a predetermined region of the insulating layer is etched to expose a predetermined region of the conductive layer, and the amorphous silicon layer is formed on the exposed conductive layer and the insulating layer.

12. The method of claim 8, further comprising forming a buffer layer between the glass substrate and the amorphous silicon layer.

13. The method of claim 9, further comprising forming a buffer layer between the glass substrate and the conductive layer.

14. The method of claim 8, wherein the electric field is applied to the conductive layer, such that stress gradient is formed in the glass substrate from a surface of the glass substrate to a depth of 10 μm thereof.

15. The method of claim 8, wherein the conductive layer is formed of molybdenum (Mo), titanium (Ti), chromium (Cr) or molybdenum-tungsten (MoW).

16. A method of fabricating a thin film transistor, comprising:
preparing a glass substrate;
forming an amorphous silicon layer pattern on the glass substrate;
forming a gate insulating layer on the amorphous silicon layer pattern;
forming a first contact hole exposing a predetermined region of the amorphous silicon layer pattern by etching a predetermined region of the gate insulating layer;
forming a gate electrode material on the gate insulating layer;
forming a semiconductor layer by crystallizing the amorphous silicon layer pattern into a polycrystalline silicon layer by applying an electric field having an energy of power density that can generate high heat of 1300° C. or more to the gate electrode material for 0.1 to 300 μs;
forming a gate electrode by patterning the gate electrode material;
forming an interlayer insulating layer on the entire surface of the glass substrate having the gate electrode;
forming a second contact hole exposing the predetermined region of the semiconductor layer exposed through the first contact hole by etching a predetermined region of the interlayer insulating layer; and
forming source and drain electrodes electrically connected to source and drain regions of the semiconductor layer through the first contact hole and the second contact hole on the interlayer insulating layer.

17. The method of claim 16, wherein the electric field is applied to the conductive layer, such that stress gradient is formed in the glass substrate from a surface of the glass substrate to a depth of 10 μm thereof.

18. The method of claim 16, wherein the gate electrode material includes molybdenum (Mo), titanium (Ti), chromium (Cr) or molybdenum-tungsten (MoW).

19. The method of claim 9, wherein the electric field is applied to the conductive layer, such that stress gradient is formed in the glass substrate from a surface of the glass substrate to a depth of 10 μm thereof.

20. The method of claim 9, wherein the conductive layer is formed of molybdenum (Mo), titanium (Ti), chromium (Cr) or molybdenum-tungsten (MoW).
